(19) United States
(12) Patent Application Publication
(10) Pub. No.: US 2018/0312995 A1
(43) Pub. Date: Nov. 1, 2018

(54) POLYCRYSTALLINE SILICON INGOT

(71) Applicant: Sino-American Silicon Products Inc., Hsinchu (TW)

(72) Inventors: Yu-Min Yang, Hsinchu (TW); Cheng-Jui Yang, Hsinchu (TW); Hung-Sheng Chou, Hsinchu (TW); Wen-Huai Yu, Hsinchu (TW); Sung-Lin Hsu, Hsinchu (TW); Wen-Ching Hsu, Hsinchu (TW)

(73) Assignee: Sino-American Silicon Products Inc., Hsinchu (TW)

(21) Appl. No.: 16/024,927

(22) Filed: Jul. 2, 2018

Related U.S. Application Data
(62) Division of application No. 15/153,744, filed on May 13, 2016.

(30) Foreign Application Priority Data
Jul. 17, 2015 (TW) 104123181

(51) Int. Cl. C30B 29/06; C30B 28/06; C01B 33/02; H01L 29/16; H01L 29/04

(52) U.S. Cl. CPC C30B 29/06; C30B 28/06; H01L 29/04; H01L 29/16; C01B 33/02

(57) ABSTRACT

The present disclosure provides a polycrystalline silicon ingot. The polycrystalline silicon ingot has a vertical direction and includes a nucleation promotion layer located at a bottom of the polycrystalline silicon ingot, and silicon grains grown along the vertical direction, wherein the silicon grains include at least three crystal directions. The coefficient of variation of grain area in a section above the nucleation promotion layer of the polycrystalline silicon ingot increases along the vertical direction.

### CROSS-REFERENCE TO RELATED APPLICATION

This application is a divisional application of and claims the priority benefit of U.S. patent application Ser. No. 15/153,744, filed on May 13, 2016, now pending. The prior application Ser. No. 15/153,744 claims the priority benefit of Taiwan application serial no. 104123181, filed on Jul. 17, 2015. The entirety of each of the above-mentioned patent applications is hereby incorporated by reference herein and made a part of this specification.

### BACKGROUND OF THE INVENTION

### Field of the Invention

The invention relates to a polycrystalline silicon ingot, and particularly relates to a polycrystalline silicon ingot having small-sized polycrystalline silicon grains grown by using a nucleation promotion layer.

### Description of Related Art

Most solar cells absorb sunlight and then produce photovoltaic effects. Currently, the solar cells are mainly made of a silicon material since the silicon material is the second most obtainable element in the world, and has advantages of low cost, nontoxic and high stability. Also, the silicon material is commonly used in semiconductor applications.

The solar cells based on the silicon material can be divided into three types of monocrystalline silicon, polycrystalline silicon and amorphous silicon. Based on the consideration of cost, polycrystalline silicon is used as a raw material of the solar cells because the cost of polycrystalline silicon is lower compared to that of monocrystalline silicon fabricated by a traditional Czochralski method (CZ method) and a floating zone method (FZ method).

### SUMMARY OF THE INVENTION

In a specific embodiment of the present disclosure, a polycrystalline silicon ingot having a vertical direction is provided. The polycrystalline silicon ingot includes a plurality of silicon grains and a nucleation promotion layer. The silicon grains are grown along the vertical direction, wherein the silicon grains include at least three crystal directions. The nucleation promotion layer is located at a bottom of the polycrystalline silicon ingot. A coefficient of variation of grain area in a section above the nucleation promotion layer of the polycrystalline silicon ingot increases along the vertical direction.

In order to make the aforementioned features and advantages of the disclosure more comprehensible, embodiments accompanied with figures are described in detail below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional diagram illustrating a polycrystalline silicon ingot according to an embodiment.

FIG. 2 to FIG. 5 are cross-sectional diagrams illustrating the fabrication of the polycrystalline silicon ingot according to some embodiments.

FIG. 6 is a metallograph illustrating a section in each region of a polycrystalline silicon brick according to some embodiments.

FIG. 7 is a metallograph illustrating a section in each region of the control group of polycrystalline silicon brick according to some embodiments.

FIG. 8 is a line graph illustrating a relationship between an average grain area and yield height of the embodiment of polycrystalline silicon brick of the present disclosure according to some embodiments and the control group.

FIG. 9 is a line graph illustrating a relationship between a standard deviation of grain area and yield height of the embodiment of polycrystalline silicon brick of the present disclosure according to some embodiments and the control group.

FIG. 10 is a line graph illustrating a relationship between a coefficient of variation of grain area and yield height of the control group of polycrystalline silicon brick according to some embodiments.

FIG. 11 is a line graph illustrating a relationship between an average grain aspect ratio and yield height of the control group of polycrystalline silicon brick according to some embodiments.

FIG. 12 is a line graph illustrating a relationship between a proportion of random grain boundary length and yield height of the control group of polycrystalline silicon brick according to some embodiments.

FIG. 13 is a line graph illustrating a relationship between an average grain aspect ratio, photoelectric conversion efficiency and yield height of the polycrystalline silicon brick according to some embodiments.

FIG. 14 is a line graph illustrating the maximum value, minimum value and average value of photoelectric conversion efficiency of the control group of polycrystalline silicon brick according to some embodiments.

FIG. 15 is a line graph illustrating a relationship between yield height and an area ratio in each crystal direction of the control group of polycrystalline silicon brick according to some embodiments.

FIG. 16 is a line graph illustrating a relationship between yield height and an area ratio in each crystal direction of the polycrystalline silicon brick according to some embodiments.

FIG. 17 is a line graph illustrating the area ratio in the crystal direction {100} in each section of the control group and embodiment of polycrystalline silicon brick according to some embodiments.

FIG. 18 is a line graph illustrating the area ratio in the crystal direction {101} in each section of the control group and embodiment of polycrystalline silicon brick according to some embodiments.

FIG. 19 is a line graph illustrating the area ratio in the crystal direction {111} in each section of the control group and embodiment of polycrystalline silicon brick according to some embodiments.

FIG. 20 is a line graph illustrating the area ratio in the crystal direction {112} in each section of the control group and embodiment of polycrystalline silicon brick according to some embodiments.

FIG. 21 is a line graph illustrating the area ratio in the crystal direction {113} in each section of the control group and embodiment of polycrystalline silicon brick according to some embodiments.

FIG. 22 is a line graph illustrating the area ratio in the crystal direction {115} in each section of the control group and embodiment of polycrystalline silicon brick according to some embodiments.

FIG. 23 is a line graph illustrating the area ratio in the crystal direction {313} in each section of the control group and embodiment of polycrystalline silicon brick according to some embodiments.

FIG. 24 is a line graph illustrating the area ratio in the crystal direction {315} in each section of the control group and embodiment of polycrystalline silicon brick according to some embodiments.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

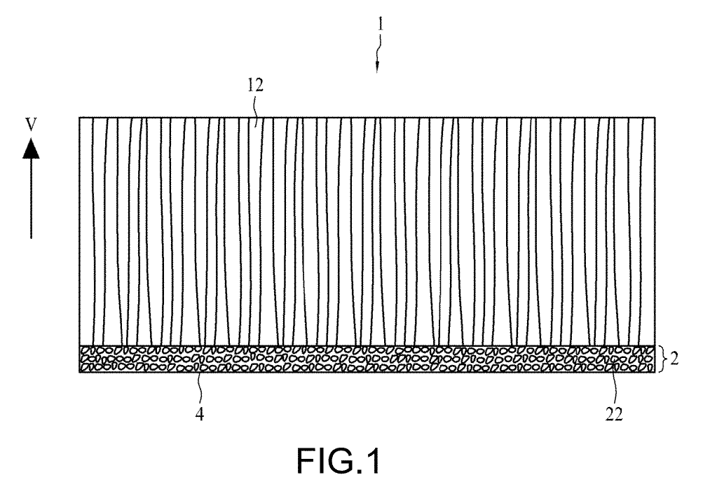

As shown in FIG. 1, a polycrystalline silicon ingot 1 of the present disclosure has a bottom 4 and a vertical direction V. In an embodiment, the polycrystalline silicon ingot 1 of the present disclosure includes a plurality of silicon grains 12 grown along the vertical direction V and a nucleation promotion layer 2 located at the bottom 4 of the polycrystalline silicon ingot 1. In an embodiment, the nucleation promotion layer 2 is composed of a plurality of crystal particles 22 with irregular shapes.

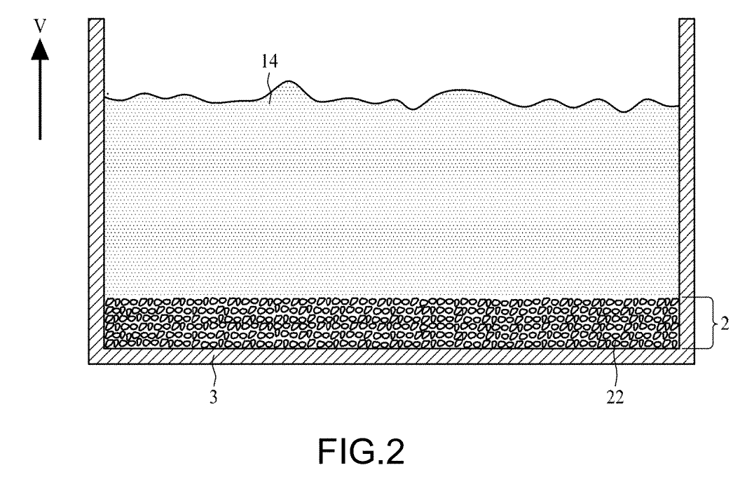

FIG. 2 to FIG. 5 are cross-sectional diagrams illustrating the fabrication of the polycrystalline silicon ingot 1 according to some embodiments. Each of the diagrams represents one or more steps.

As shown in FIG. 2, the plurality of crystal particles 22 are spread over the bottom of a mold 3 (e.g., quartz crucible) to form the nucleation promotion layer 2. The mold 3 itself defines the vertical direction V, and is a trough-like container capable of withstanding high temperature without melting. The crystal particles 22 are made of a material having a melting point higher than about 1400° C., for example, high purity graphite, silicon, or ceramic materials like aluminum oxide, silicon carbide, silicon nitride, and aluminum nitride. In an embodiment, the crystal particles 22 made of polycrystalline silicon or monocrystalline silicon chips are spread over the bottom of the mold 3 so as to form the nucleation promotion layer 2. The placement method, stacking method and filling density for spreading over the chips are not limited (e.g., can be close-packed arrangement in regular or be arbitrarily poured in). The average particle size of the nucleation promotion layer 2 is less than 50 mm, while the average stacked height is not limited. In an embodiment, the average particle size of the nucleation promotion layer 2 is less than 10 mm, and the average stacked height is equal to or more than 5 mm.

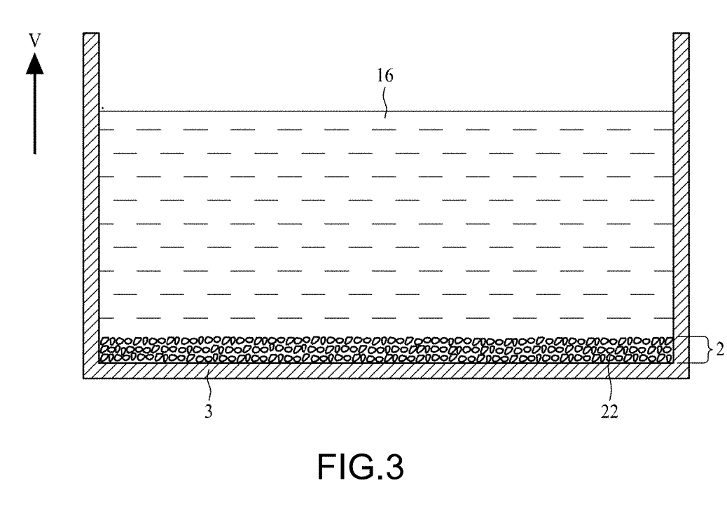

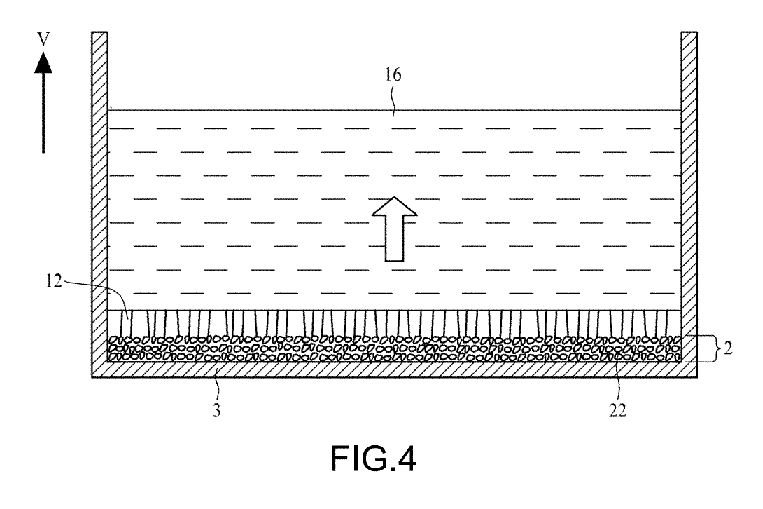

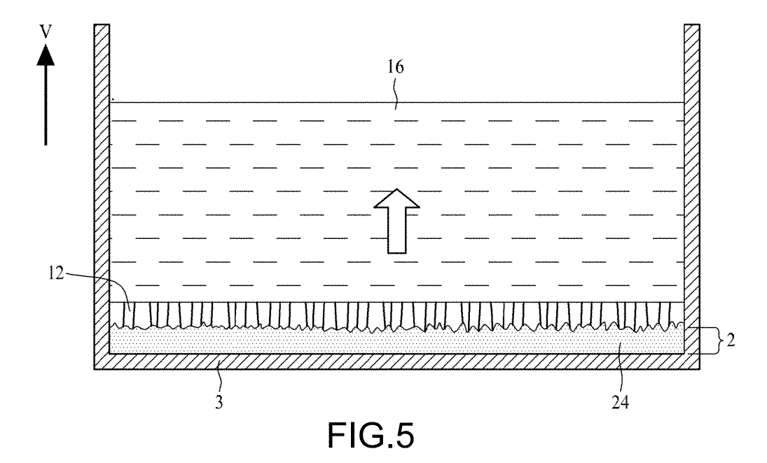

Next, a silicon raw material 14 is placed in the mold 3 and located above the nucleation promotion layer 2. The mold 3 filled with the nucleation promotion layer 2 and the silicon raw material 14 is placed in a directional solidification system crystal growth furnace (not shown), and the silicon raw material 14 is completely melted into a silicon melt 16, as shown in FIG. 3. The nucleation promotion layer 2 may not be melted or may be partially melted, wherein the height of the unmelted nucleation promotion layer is equal to or more than about 100 μm. Then, as shown in FIG. 4, the mold 3 is cooled based on the directional solidification process that causes the plurality of silicon grains 12 in the silicon melt 16 are nucleated above the nucleation promotion layer 2. The plurality of silicon grains 12 are gradually nucleated at the interface between the nucleation promotion layer 2 and the silicon melt 16 and grown along the vertical direction V. In another embodiment, as shown in FIG. 5, the nucleation promotion layer 2 may be a plate 24. The plate 24 is made of a material having a melting point higher than about 1400° C., for example, high purity graphite, silicon, or ceramic materials like aluminum oxide, silicon carbide, silicon nitride, and aluminum nitride. The surface of the plate 24 in contact with the silicon melt 16 has a roughness of 300 μm to 1000 μm so as to provide the plurality of silicon grains 12 with a plurality of nucleation points.

Lastly, the mold 3 is continuously cooled based on the directional solidification process such that the plurality of silicon grains 12 are continuously grown along the vertical direction V until the silicon melt 16 is completely solidified, so as to obtain the polycrystalline silicon ingot 1 as shown in FIG. 1. After the polycrystalline silicon ingot 1 is taken out from the mold 3, four parts of side walls of the polycrystalline silicon ingot 1 are cut off, and then subdivided into multiple polycrystalline silicon bricks (e.g., 4×4=16 or 5×5=25 of bricks). After that, the test is performed by using a silicon wafer or brick carrier lifetime tester (u-PCD; Microwave Lifetime Tester). The method to use the carrier lifetime tester is that, one of the regions of the polycrystalline silicon brick is irradiated by a laser pulse using a measuring head to excite electrons and holes, and then the region excited by the laser pulse is irradiated by a microwave. The time of separation and combination of the carrier in the silicon crystal is measured. Then, the measuring head is moved so that the measurement is performed by the measuring head along the vertical direction V. Therefore, a curve of the carrier lifetime corresponding to each height in the vertical direction V is formed.

After the carrier lifetime of each part of the polycrystalline silicon brick is obtained, the part of the polycrystalline silicon brick which does not meet the specific carrier lifetime is further removed (e.g., the nucleation promotion layer 2 at the bottom of the polycrystalline silicon brick and part of the top thereof), such that yield embodiment of polycrystalline silicon brick can be cut out from the polycrystalline silicon brick. After that, the embodiment of polycrystalline silicon brick can be cut into wafers with a specific thickness. In an embodiment, the embodiment of polycrystalline silicon brick can be equally cut into three regions of a bottom region, an intermediate region and a top region. In the following description, the embodiment of polycrystalline silicon brick is 300 mm as an example to describe. However, the invention is not limited thereto. In an embodiment, the carrier lifetime at either end of the embodiment of polycrystalline silicon brick is equal to or more than 2.0×10⁻⁶ seconds, and the carrier lifetime at any part thereof is more than 2.0×10⁻⁶ seconds. The bottom end of the embodiment of polycrystalline silicon brick is defined as 0 mm (the end close to the original nucleation promotion layer 2) which increases along the vertical direction V, while the top end of the embodiment of polycrystalline silicon brick is defined as 300 mm. The embodiment of polycrystalline silicon brick at the yield height within the range of 0 mm to 100 mm is defined as the bottom region (the range lower than 100 mm); the embodiment of polycrystalline silicon brick at the yield height within the range of 100 mm to 200 mm is defined as the intermediate region; and the embodiment of polycrystalline silicon brick at the yield height within the range of 200 mm to 300 mm is defined as the top region.

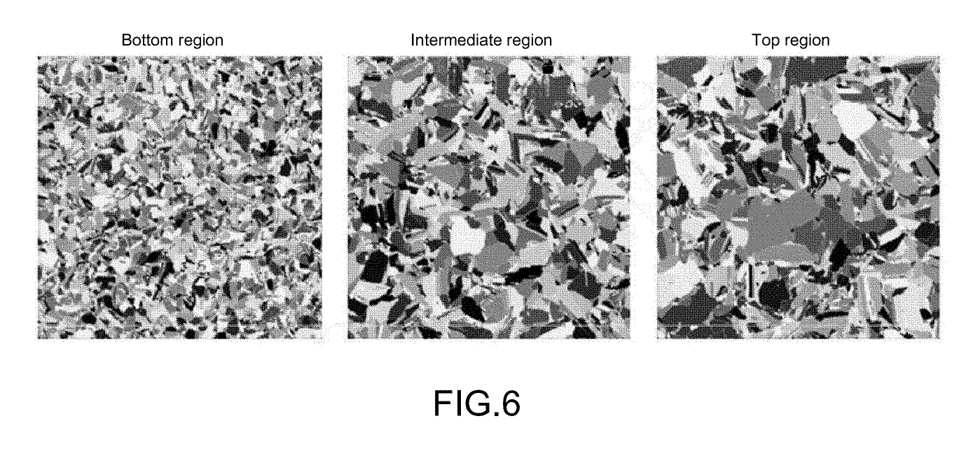

FIG. 6 shows the metallograph of the grain distribution and the silicon grain size thereof in each of a section in the bottom region, the intermediate region and the top region of the embodiment of polycrystalline silicon brick. In the crystal growth process of the embodiment of polycrystalline silicon brick, the plurality of crystal particles are spread over the bottom of the mold as the nucleation promotion layer. From FIG. 6, it is obvious that the area of each grain in the bottom region is smaller and the grain number is larger. The grain size increases with the increase of the yield height, and thus the area of each grain in the top region is larger and the grain number is smaller.

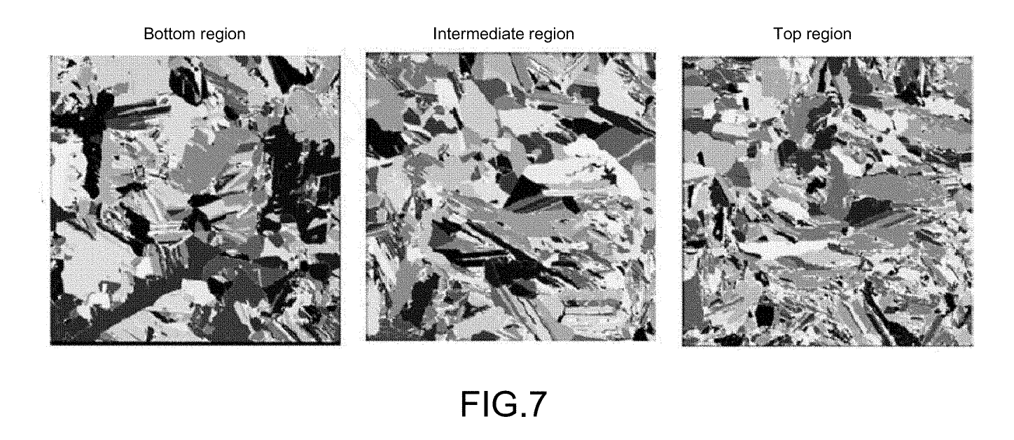

FIG. 7 shows the control group of polycrystalline silicon brick fabricated by the proposed method according to current technology, such as the method of partial undercooling or adding a crystal seed layer. Similarly, the yield region having the carrier lifetime at either end that is equal to or more than 2.0×10⁻⁶ seconds is cut out. The total length of the control group of polycrystalline silicon brick is 300 mm. Also, FIG. 7 shows the metallograph of the grain distribution and the silicon grain size thereof in each of a section in the bottom region (the yield height within the range of 0 mm to 100 mm), the intermediate region (the yield height within the range of 100 mm to 200 mm) and the top region (the yield height within the range of 200 mm to 300 mm) of the control group of polycrystalline silicon brick respectively. In the crystal growth process of the control group of polycrystalline silicon brick, the plurality of crystal particles are not spread over the bottom of the mold. In other words, the nucleation promotion layer is not used.

From the bottom region (the yield height of 0 mm to 100 mm) of the control group of polycrystalline silicon brick in FIG. 7, it is clearly understood that in the crystal growth process of the control group of polycrystalline silicon ingot, large grains are grown at the bottom of the crucible, such that a section of the bottom region of the control group of polycrystalline silicon ingot has a larger average grain area. However, the defect density rapidly increases in the extension growth, resulting in the deterioration of the overall crystal quality of the control group of polycrystalline silicon brick, and the photoelectric conversion efficiency of the solar cells which are subsequently fabricated is lower. In comparison with the control group of polycrystalline silicon ingot, the crystal growth of the polycrystalline silicon ingot is that, the nucleation promotion layer 2 is used to directly provide the silicon melt 16 with the concentrated nucleation points, so as to significantly reduce the distribution ratio of the large-sized silicon grains. Thus, a section in the bottom region (the yield height of 0 mm to 100 mm) of the embodiment of polycrystalline silicon brick has a smaller average grain area, as shown in FIG. 6. Since the distribution of the small-sized silicon grains is concentrated and the grain size is similar, the case that large grains eat small grains is reduced. Thus, the grains easily tend to grow in a single direction, mainly along the reverse direction of the cooling direction to grow, as shown the vertical direction V in FIG. 1, so as to avoid that the columnar crystal can not grow from the bottom to the top completely. Additionally, the grain boundary with high distribution density in the polycrystalline silicon ingot in the crystal growth process, the defects can be concentrated attracted by the stress field or the thermal stress is released by sliding on the grain boundary, so as to suppress the issue of the rapid increase of dislocation defects, thereby allowing the overall polycrystalline silicon ingot has a better crystal quality. Also, the photoelectric conversion efficiency of the solar cells which are subsequently fabricated is also higher.

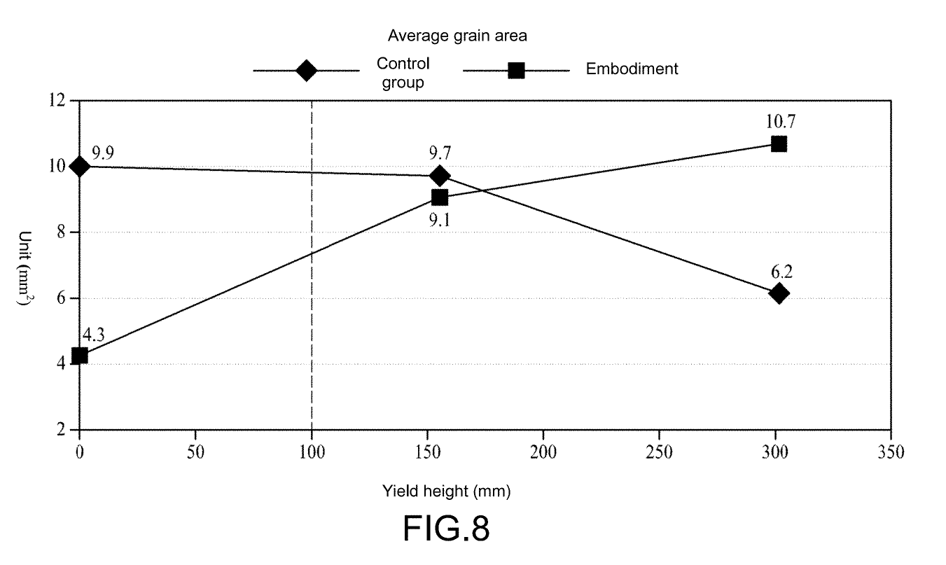

Furthermore, the metallographs of FIG. 7 and FIG. 8 are measured by a grain measurement equipment, such as a grain detector which can detect the grain boundary, and the actual area and each analysis value (e.g., average grain area (mean value; the definition of paragraph 15.2 of page 12 of E122-10), standard deviation of grain area (the definition of paragraph 15.3 of page 12 of E122-10), grain number, and grain aspect ratio) of the grains in each section are calculated according to the standard test regulation of E112-10 standard test methods for determining average grain size published by ASTM international. The reflection situation under different light conditions is detected by the grain detector, and the measurement time is about 10 seconds/each wafer. The results and comparisons are described as below.

FIG. 8 shows the comparison of the average grain area between the embodiment of polycrystalline silicon brick and the control group of polycrystalline silicon brick cut out from the polycrystalline silicon ingot. The horizontal axis indicates the yield height of the two (unit:mm), and the vertical axis indicates the average grain area (unit:mm²). Each measuring point represents the average grain area corresponding to the section of the polycrystalline silicon brick at the corresponding yield height. The embodiment of polycrystalline silicon brick is cut into a plurality of polycrystalline silicon wafers, and the thickness of each wafer is between 150 μm and 350 μm. Because of the thin thickness, it can be regarded as that both surfaces have the same grain boundary distribution. The average grain area in the section at the yield height of 0 mm (namely, a polycrystalline silicon wafer cut out from the region at the yield height of 0 mm, and so on) of the embodiment of polycrystalline silicon brick is 4.3 mm²; the average grain area in the section at the yield height of 150 mm is 9.1 mm²; and the average grain area in the section at the yield height of 300 mm is 10.7 mm². Relatively speaking, the average grain area in the section at the yield height of 0 mm of the control group of polycrystalline silicon brick is 9.9 mm²; the average grain area in the section at the yield height of 150 mm is 9.7 mm²; and the average grain area in the section at the yield height of 300 mm is 6.2 mm².

The average grain area in any section of the embodiment of polycrystalline silicon brick is between about 4 mm² and 11 mm². Moreover, the average grain area in any section in the bottom region (the yield height within the range of 100 mm) of the embodiment of polycrystalline silicon brick is less than 8 mm², while the smaller grain area is controlled by the nucleation promotion layer 2. By contrast, the average grain area in any section in the bottom region of the control group is about 9.7 mm² to 9.9 mm², which is larger than the average grain area in any section in the bottom region of the embodiment of polycrystalline silicon brick. The average grain area in each section of the embodiment of polycrystalline silicon brick also increases with the increase of the yield height.

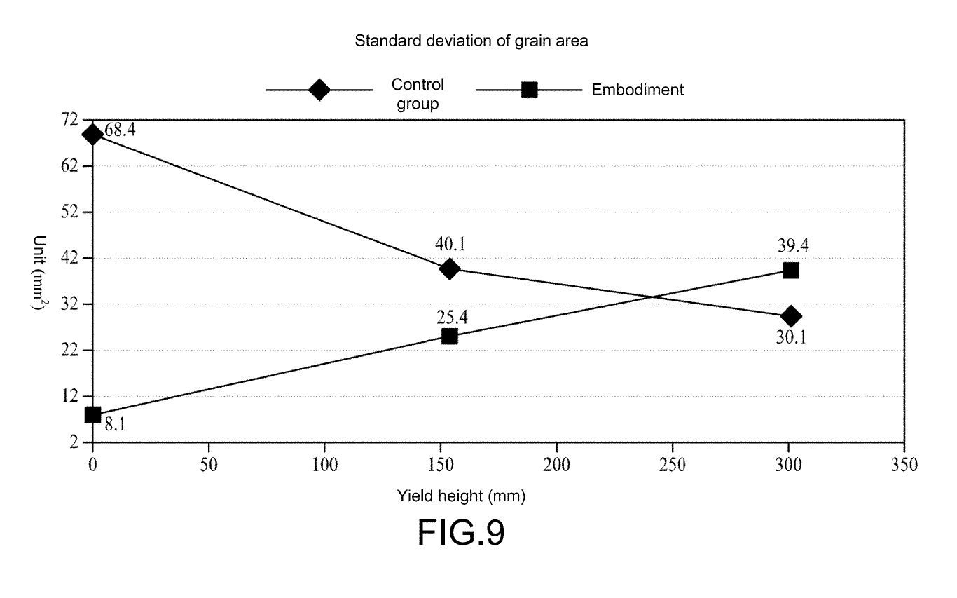

FIG. 9 shows the comparison of the standard deviation of grain area between the embodiment of polycrystalline silicon brick and the control group of polycrystalline silicon brick. The horizontal axis indicates the yield height of the two (unit:mm), and the vertical axis indicates the standard deviation of grain area (unit:mm²). Each measuring point represents how much of the standard deviation of grain area (mm²) corresponding to the section at the yield height. The calculating method of the standard deviation of grain area is that, a section is cut down from the polycrystalline silicon brick. The average grain area in the section is measured first. Differences between the area of each of the silicon grains and the average grain area are obtained. Then, square root an average value of the squared differences, so as to obtain the standard deviation of grain size, wherein the average value of the squared differences is equal to divide the sum of the squared differences by the calculated grain number. The formula is shown below:

$$σ ( μ ) = \sqrt{\frac{1}{N} {\sum }_{i = 1}^{N} {( {x}_{i} - μ )}^{2}}$$

N is the number of all the grains in the section; Xᵢ is the value of each grain area; μ is the average value of all the grain area in the section. In short, the standard deviation of grain area is a dispersion degree of a group of grain area values from the average grain area value. A larger standard deviation of grain area represents a larger difference between most of the grain area values and the average grain area value thereof (each grain area value is far away from the average grain area value); a smaller standard deviation of grain area represents that each grain area value is close to the average grain area value thereof, and the difference between each grain area is smaller. The proportion of the total grain number occupied by the grain number within the grain area range which is greater than or less than one standard deviation of grain area from the average grain area value (equal to μ±c) is 68% in a normal distribution; the proportion of the total grain number occupied by the grain number within the grain area range which is within two standard deviation of grain area (equal to μ±2σ) is 95%; and the proportion of the total grain number occupied by the grain number within the grain area range which is within three standard deviation of grain area (equal to μ±3σ) is 99.7%.

The standard deviation of grain area in the section at the yield height of 0 mm (namely, a polycrystalline silicon wafer cut out from the region at the yield height of 0 mm, and so on) of the embodiment of polycrystalline silicon brick is 8.1 mm²; the standard deviation of grain area in the section at the yield height of 150 mm is 25.4 mm²; and the standard deviation of grain area in the section at the yield height of 300 mm is 39.4 mm². The standard deviation of grain area of the embodiment of polycrystalline silicon brick increases with the increase of the yield height. Relatively speaking, the standard deviation of grain area in the section at the yield height of 0 mm of the control group of polycrystalline silicon brick is 68.4 mm²; the standard deviation of grain area in the section at the yield height of 150 mm is 40.1 mm²; and the standard deviation of grain area in the section at the yield height of 300 mm is 30.1 mm². The standard deviation of grain area of the control group of polycrystalline silicon brick decreases with the increase of the yield height. By contrast, the standard deviation of grain area in any section in the bottom region (the yield height is less than 100 mm) of the embodiment of polycrystalline silicon brick is less than 22 mm², which is far lower than the standard deviation of grain area in any section in the bottom region of the control group of polycrystalline silicon brick (more than 50 mm²). Each grain area in a section in the bottom region of the embodiment of polycrystalline silicon brick is close to the average gain area value of the section. That is, the embodiment of polycrystalline silicon brick has a higher concentrated grain size. For example, in the section at the yield height of 0 mm, the grain number having the grain area within the range of 4.3±8.1 mm² is 68%; and the grain number having the grain area within the range of 4.3±(2×8.1) mm² is 95%. On the contrary, the distribution of each grain area distribution in any section in the bottom region of the control group of polycrystalline silicon brick is more dispersed, which shows an uneven size distribution. For example, in the section at the yield height of 0 mm of the control group of polycrystalline silicon brick, the grain number having the grain area within the range of 9.9±68.4 mm² is 68%; and the grain number having the grain area within the range of 9.9±(2×68.4) mm² is 95%, which shows that the size distribution of the grain area in the bottom region of the control group of polycrystalline silicon brick is very dispersed, and the size of the grain area is uneven.

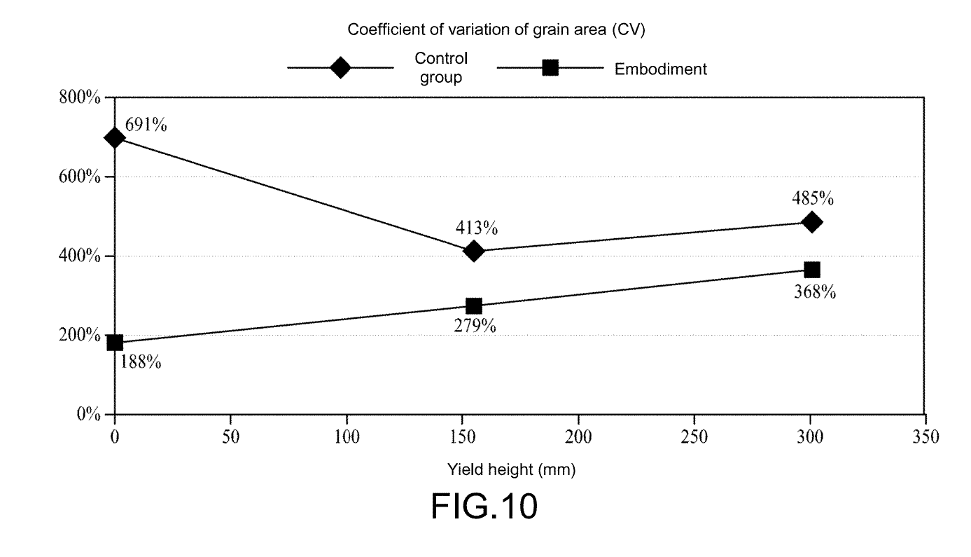

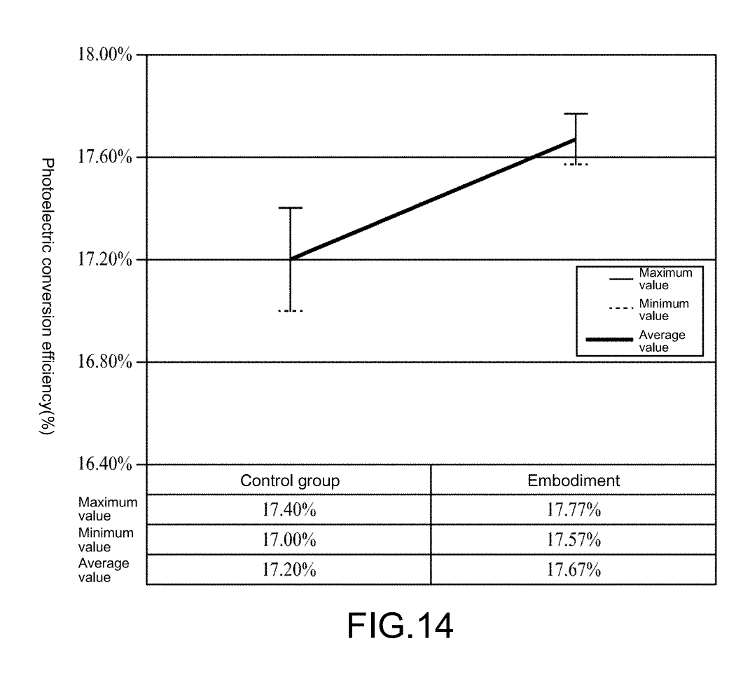

FIG. 10 shows the comparison of the coefficient of variation of grain area between the embodiment of polycrystalline silicon brick and the control group of polycrystalline silicon brick. The horizontal axis indicates the yield height of the two (unit:mm), and the vertical axis indicates the value of coefficient of variation of grain area (unit: %). Each measuring point represents how much of the value of coefficient of variation of grain area (%) corresponding to the section at the yield height. The coefficient of variation of grain area is defines as the standard deviation of grain area in a section divided by the average grain area in the section (can be regarded as the normalization of the standard deviation of grain area). A smaller coefficient of variation of grain area represents that the grain area is more even and close to the average grain area in the section, which is equal to that the grain area distribution is more concentrated. On the other hand, a larger coefficient of variation of grain area represents that the grain area in the section is irregular, and the size distribution of the grain area is uneven. The coefficient of variation of grain area in the section at the yield height of 0 mm (namely, a polycrystalline silicon wafer cut out from the region at the yield height of 0 mm, and so on) of the embodiment of polycrystalline silicon brick is 188%; the coefficient of variation of grain area in the section at the yield height of 150 mm is 279%; and the coefficient of variation of grain area in the section at the yield height of 300 mm is 368%. The coefficient of variation of grain area of the embodiment of polycrystalline silicon brick increases with the increase of the yield height. The coefficient of variation of grain area in a section of the embodiment of polycrystalline silicon brick is in a range of about 150% to 400%, and in a linear relationship; and the coefficient of variation of grain area in any section of the embodiment of polycrystalline silicon brick is all less than 370%. The coefficient of variation of grain area in the section at the yield height of 0 mm of the control group of polycrystalline silicon brick is 691%; the coefficient of variation of grain area in the section at the yield height of 150 mm is 413%; and the coefficient of variation of grain area in the section at the yield height of 300 mm is 485%. There is no linear relationship between the yield height and the coefficient of variation of grain area of the control group of polycrystalline silicon brick. The coefficient of variation of grain area in a section of the embodiment of polycrystalline silicon brick is in a range of about 150% to 400%. After the photoelectric efficiency of each section of the embodiment of polycrystalline silicon brick and each section of the control group of polycrystalline silicon brick are measured, it can be learned that, the photoelectric conversion efficiency (average value is 17.67%) in any section of the embodiment of polycrystalline silicon brick is higher than the photoelectric conversion efficiency (average value is 17.20%) in any section of the control group of polycrystalline silicon brick. Thus, the overall embodiment of polycrystalline silicon brick has better photoelectric conversion efficiency, as shown in following FIG. 14 and detailed description.

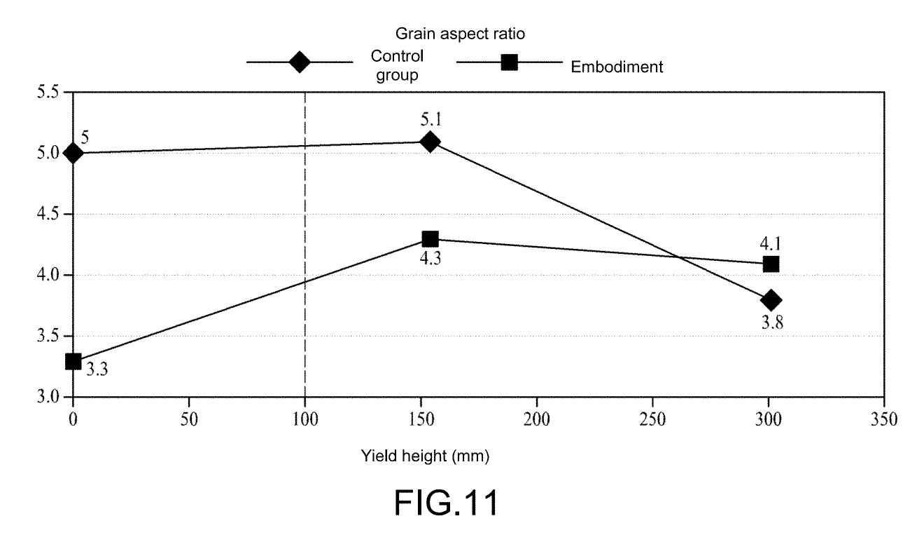

FIG. 11 shows the comparison of the average grain aspect ratio between each section of the embodiment of polycrystalline silicon brick and the control group of polycrystalline silicon brick. The horizontal axis indicates the yield height of the two (unit:mm), and the vertical axis indicates the average grain aspect ratio. Each measuring point represents how much of the average grain aspect ratio corresponding to the section at the yield height. The aspect ratio is defined as the ratio of the longest axis and the shortest axis in the gain boundary in the same grain. Thus, a larger aspect ratio represents that the shape thereof is more like an ellipse; on the contrary, when the aspect ratio is 1, the shape is equal to a circle. The average grain aspect ratio in a section of the embodiment of polycrystalline silicon brick is between about 3.0 and 4.5. The average grain aspect ratio in the section at the yield height of 0 mm (namely, a polycrystalline silicon wafer cut out from the region at the yield height of 0 mm, and so on) of the embodiment of polycrystalline silicon brick is 3.3; the average grain aspect ratio in the section at the yield height of 150 mm is 4.3; and the average grain aspect ratio in the section at the yield height of 300 mm is 4.1. The average grain aspect ratio in a section in the bottom region (the yield height is less than 100 mm) of the embodiment of polycrystalline silicon brick is between about 3 and 4, which represents that the grains in a section in the bottom region are mostly present in the ratio of long axis and short axis of 3 to 4. The average grain aspect ratio in the section at the yield height of 0 mm of the control group of polycrystalline silicon brick is 5; the average grain aspect ratio in the section at the yield height of 150 mm is 5.1; and the average grain aspect ratio in the section at the yield height of 300 mm is 3.8. By contrast, the average grain aspect ratio in a section in the bottom region of the control group of polycrystalline silicon brick is about 5, which is larger than the average grain aspect ratio in a section in the bottom region of the embodiment of polycrystalline silicon brick (less than 4).

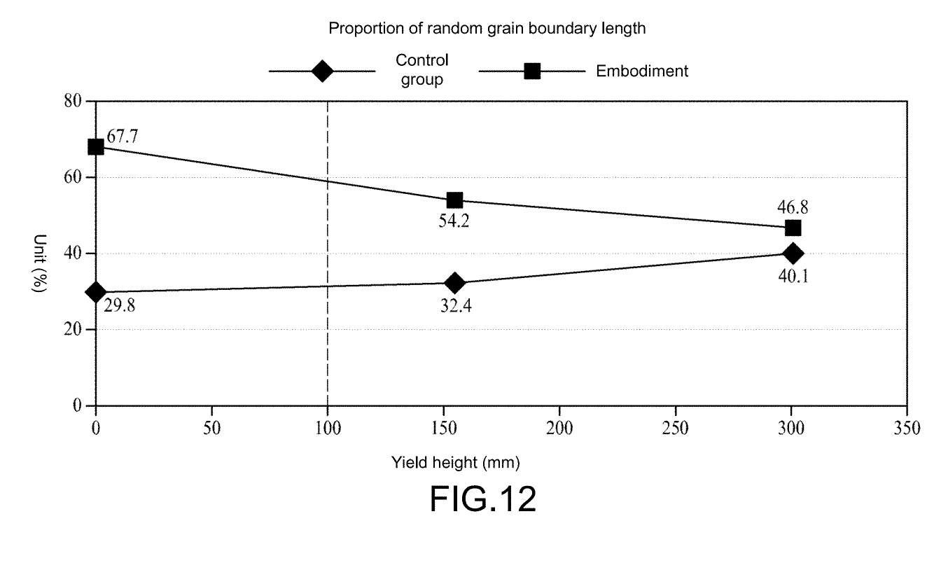

FIG. 12 shows the comparison of the proportion of random grain boundary length between the embodiment of polycrystalline silicon brick and the control group of polycrystalline silicon brick. The horizontal axis indicates the yield height of the two (unit:mm), and the vertical axis indicates how much of the proportion of the total grain boundary length in a section occupied by the random grain boundary length in the section. In a section, the grain boundary can be divided into two types of small-angle grain boundary and large-angle grain boundary. The small-angle grain boundary refers to the grain boundary that the rotation angle between two adjacent grains is less than 10 degrees, while the large-angle grain boundary refers to the grain boundary that the rotation angle is more than 10 degrees. According to the common bit grain boundary model, the large-angle grain boundary can be also divided into a special grain boundary (also known as a coincidence site lattice (CSL); represented by Σ value, such as Σ3 [symbol] Σ9 and Σ27-type grain boundaries) and a normal boundary (also known as a random grain boundary (random)). The number of the Σ value is the regularity performance of the lattice arrangement on both sides of the grain boundary. The spot arrays of two adjacent grains are extended to the space respectively, so that they are interspersed with each other, and some of spot arrays are overlapped. A smaller number represents a higher degree of overlap in the lattice arrangement on both sides of the grain boundary, and the grain boundary energy is also lower. For example, Σ3-type grain boundary is a shallow energy level complex center, while the other grain boundary is a deep energy level complex center.

It can be learned from FIG. 12 that, the proportion of the random grain boundary length in a section of the embodiment of polycrystalline silicon brick is between about 45% and 70%. The proportion of the random grain boundary length in the section at the yield height of 0 mm (namely, a polycrystalline silicon wafer cut out from the region at the yield height of 0 mm, and so on) of the embodiment of polycrystalline silicon brick is 67.7%; the proportion of the random grain boundary length in the section at the yield height of 150 mm is 54.2%; and the proportion of the random grain boundary length in the section at the yield height of 300 mm is 46.8%. Particularly, the proportion of the random grain boundary length of in a section in the bottom region (the yield height is less than 100 mm) is more than 60%. The proportion of the random grain boundary length in the section at the yield height of 0 mm of the control group of polycrystalline silicon brick is 29.8%; the proportion of the random grain boundary length in the section at the yield height of 150 mm is 32.4%; and the proportion of the random grain boundary length in the section at the yield height of 300 mm is 40.1%. The proportion of the random grain boundary length in a section of the control group of polycrystalline silicon brick is between about 29.8% and 40.1%. Obviously, all the proportion of the random grain boundary length in a section at each yield height of the embodiment of polycrystalline silicon brick is larger than the proportion of the random grain boundary length in a section of the control group of polycrystalline silicon brick. Experiments confirmed that the ability to attract metal impurities to deposit of the random grain boundary is larger than that of the grain boundary with high Σ value, and the ability to attract the metal impurities of the grain boundary with low Σ value is the weakest. The random grain boundary length in any section of the embodiment of polycrystalline silicon brick is about 45% to 70% of the total grain boundary length in the section. The proportion of the random grain boundary is increased to another degree compared to the normal process, so that most of the metal impurities are attracted and accumulated in the grain boundary. Thus, in the growth process of the polycrystalline silicon ingot, the metal impurities which are segregated in the grains can be reduced, thereby enhancing the photoelectric conversion efficiency of the embodiment of polycrystalline silicon brick.

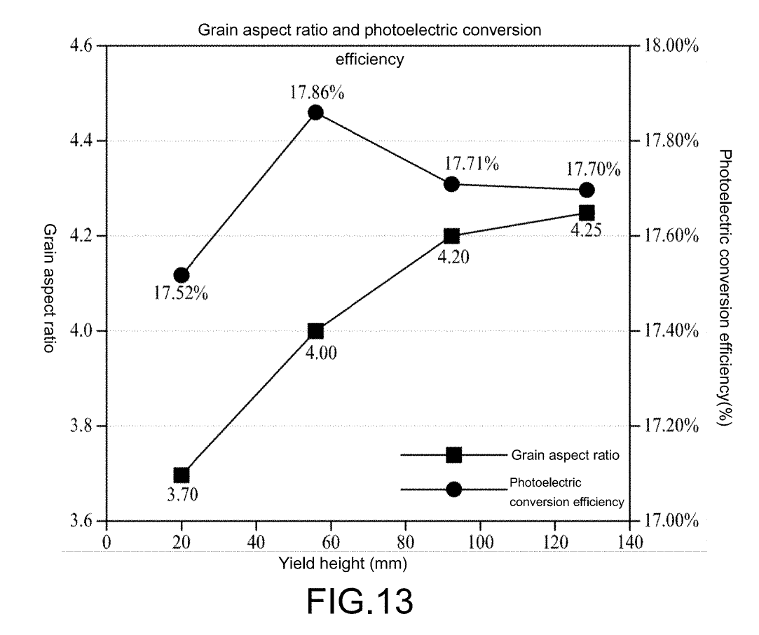

FIG. 13 shows the measurement values of the grain aspect ratio and the photoelectric conversion efficiency of the embodiment of polycrystalline silicon brick. The horizontal axis indicates the yield height (unit:mm), the left vertical axis indicates the average grain aspect ratio, and the right vertical axis indicates the photoelectric conversion efficiency (unit: %). Each measuring point represents how much of the average grain aspect ratio and the photoelectric conversion efficiency thereof corresponding to the section at the yield height. The photoelectric conversion efficiency is the efficiency of conversion of light energy into electric energy. The test equipment for the solar cells use the standard spectrum of AM1.5G. The spectrum is obtained according to the actual spectrum of AM1.5G after artificial modification, and the light intensity thereof is 1000 W/m². When the average grain aspect ratio of the embodiment of polycrystalline silicon brick is 3.7, the photoelectric conversion efficiency thereof is 17.52%, and the measuring point is the section at the yield height of about 20 mm. When the average grain aspect ratio is 4.00, the photoelectric conversion efficiency thereof is 17.86%, and the measuring point is the section at the yield height of about 50 mm to 60 mm. When the average grain aspect ratio is 4.20, the photoelectric conversion efficiency thereof is 17.71%, and the measuring point is the section at the yield height of about 90 mm to 100 mm. When the average grain aspect ratio is 4.25, the photoelectric conversion efficiency thereof is 17.70%, and the measuring point is the section at the yield height of about 120 mm to 130 mm. Thus, it can be learned that, when the average grain aspect ratio is between 3.80 and 4.25, the photoelectric conversion efficiency is more than 17.60%, and the section is at the yield height of about 30 mm to 130 mm. The polycrystalline silicon brick with the average grain aspect ratio of 3.80 to 4.25 has the best photoelectric conversion efficiency. That is, the efficiency of conversion of light energy into electric energy is the highest. It is not as the original prediction that, the higher or the lower the average grain aspect ratio, the better the photoelectric conversion efficiency.

FIG. 14 shows the comparison of the photoelectric conversion efficiency between the embodiment of polycrystalline silicon brick and the control group of polycrystalline silicon brick. The vertical axis indicates the photoelectric conversion efficiency (unit: %). It can be learned the maximum value, the minimum value and the overall average value of the photoelectric conversion efficiency of the all yield of the embodiment of polycrystalline silicon brick and the control group of polycrystalline silicon brick. The maximum value of the photoelectric conversion efficiency of the embodiment of polycrystalline silicon brick can be up to 17.77%; the minimum value of the photoelectric conversion efficiency can achieve 17.57%; and the average value of the overall photoelectric conversion efficiency is 17.67%. The maximum value of the photoelectric conversion efficiency of the control group of polycrystalline silicon brick can be up to 17.40%; the minimum value of the photoelectric conversion efficiency can achieve 17.00%; and the average value of the overall photoelectric conversion efficiency is 17.20%. By contrast, the average photoelectric conversion efficiency (17.67%) of the embodiment of polycrystalline silicon brick is more than the average photoelectric conversion efficiency (17.20%) of the control group of polycrystalline silicon brick about 0.47% to 0.5%, and the minimum value (17.57%) of the photoelectric conversion efficiency of the embodiment of polycrystalline silicon brick is still more than the maximum value (17.40%) of the photoelectric conversion efficiency of the control group polycrystalline silicon brick. Therefore, the overall photoelectric conversion efficiency of the embodiment of polycrystalline silicon brick is more than the photoelectric conversion efficiency of the control group of polycrystalline silicon brick. That is, the embodiment of polycrystalline silicon brick has better photoelectric conversion efficiency.

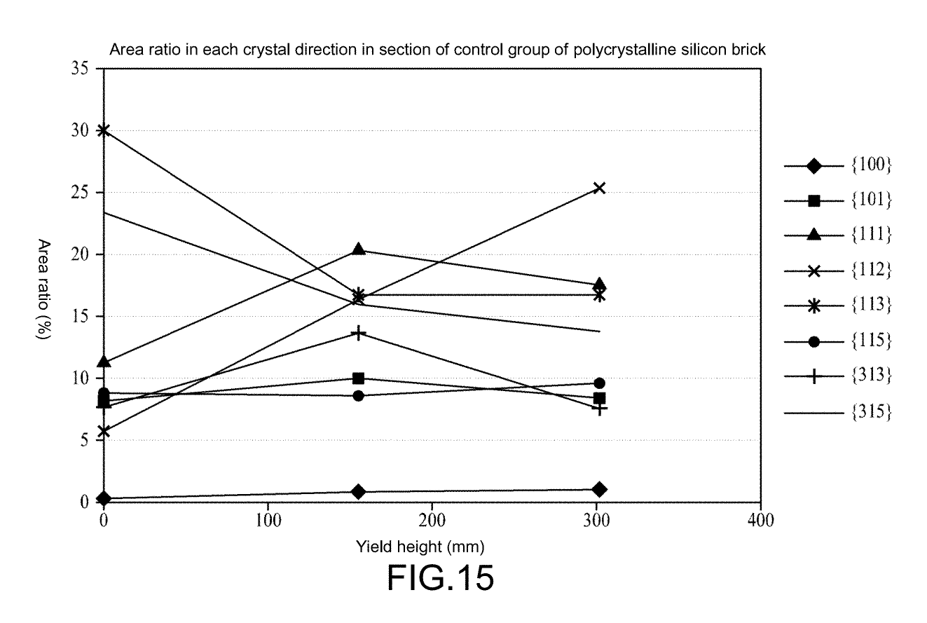

FIG. 15 shows a line graph of a relationship between the yield height and the area ratio in a crystal direction of the control group of polycrystalline silicon brick, and the crystallographic analysis is performed by electron back-scattered diffraction (EBSD). The horizontal axis indicates the yield height (unit:mm), and the vertical axis indicates the area ratio in each crystal direction in the section. It can be learned from the measurement that, the proportion of the silicon grain area in the total crystal direction in a section occupied by the area percentage of the silicon grain having the crystal direction {100} in the section between the yield height of the control group of polycrystalline silicon brick is between about 0% and 1%; the proportion of the silicon grain in the crystal direction {101} is between about 8% and 10%; the proportion of the silicon grain in the crystal direction {111} is between about 10% and 20%; the proportion of the silicon grain in the crystal direction {112} is between about 5% and 25%; the proportion of the silicon grain in the crystal direction {113} is between about 16% and 30%; the proportion of the silicon grain in the crystal direction {115} is between about 8% and 10%; the proportion of the silicon grain in the crystal direction {313} is between about 6% and 14%; and the proportion of the silicon grain in the crystal direction {315} is between about 14% and 24%.

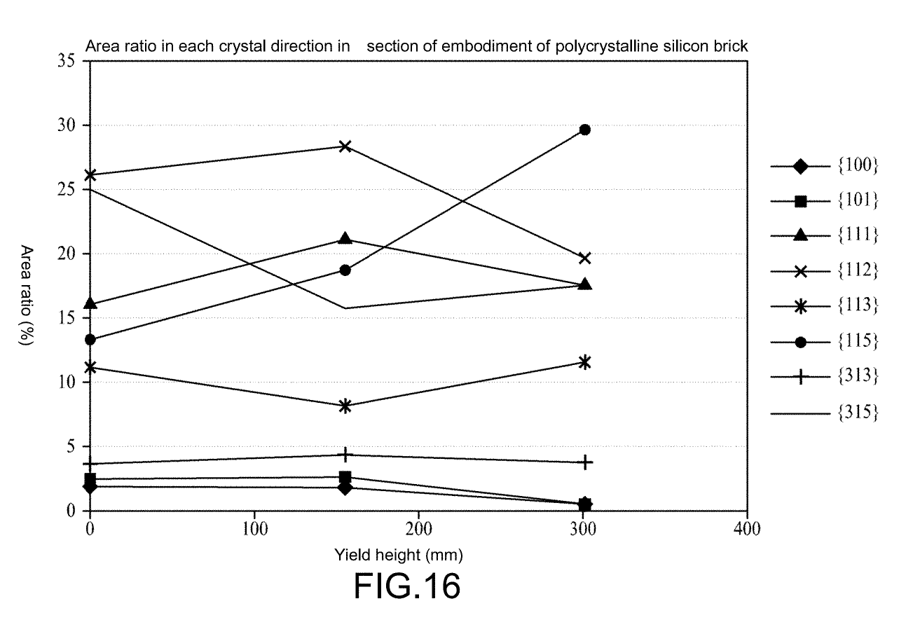

FIG. 16 shows a line graph of a relationship between the yield height and the area ratio in a crystal direction of the embodiment of polycrystalline silicon brick. The horizontal axis indicates the yield height (unit:mm), and the vertical axis indicates the ratio in each crystal direction in the section. It can be learned from the measurement that, the proportion of the silicon grain area in the total crystal direction in a section occupied by the area percentage of the silicon grain having the crystal direction {100} in the section between the yield height of the embodiment of polycrystalline silicon brick is between about 0% and 3%; the proportion of the silicon grain in the crystal direction {101} is between about 0% and 3%; the proportion of the silicon grain in the crystal direction {111} is between about 16% and 21%; the proportion of the silicon grain in the crystal direction {112} is between about 20% and 29%; the proportion of the silicon grain in the crystal direction {113} is between about 7% and 12%; the proportion of the silicon grain in the crystal direction {115} is between about 13% and 30%; the proportion of the silicon grain in the crystal direction {313} is between about 3% and 5%; and the proportion of the silicon grain in the crystal direction {315} is between about 15% and 25%. The proportion of the silicon grain area in the total crystal direction in a section occupied by the area percentage of the silicon grain having the crystal direction {100} in the section at the yield height of about 0 mm of the embodiment of polycrystalline silicon brick is about 2%; the proportion of the silicon grain in the crystal direction {101} is about 3%; the proportion of the silicon grain in the crystal direction {111} is about 16%; the proportion of the silicon grain in the crystal direction {112} is about 26%; the proportion of the silicon grain in the crystal direction {113} is about 11%; the proportion of the silicon grain in the crystal direction {115} is about 13%; the proportion of the silicon grain in the crystal direction {313} is about 4%; and the proportion of the silicon grain in the crystal direction {315} is about 25%. The proportion of the silicon grain area in the total crystal direction in a section occupied by the area percentage of the silicon grain having the crystal direction {100} in the section at the yield height of about 150 mm of the embodiment of polycrystalline silicon brick is about 2%; the proportion of the silicon grain in the crystal direction {101} is about 3%; the proportion of the silicon grain in the crystal direction {111} is about 21%; the proportion of the silicon grain in the crystal direction {112} is about 28%; the proportion of the silicon grain in the crystal direction {113} is about 8%; the proportion of the silicon grain in the crystal direction {115} is about 18%; the proportion of the silicon grain in the crystal direction {313} is about 4%; and the proportion of the silicon grain in the crystal direction {315} is about 16%. The proportion of the silicon grain area in the total crystal direction in a section occupied by the area percentage of the silicon grain having the crystal direction {100} in the section at the yield height of about 300 mm of the embodiment of polycrystalline silicon brick is about 0%; the proportion of the silicon grain in the crystal direction {101} is about 0%; the proportion of the silicon grain in the crystal direction {111} is about 18%; the proportion of the silicon grain in the crystal direction {112} is about 20%; the proportion of the silicon grain in the crystal direction {113} is about 12%; the proportion of the silicon grain in the crystal direction {115} is about 29%; the proportion of the silicon grain in the crystal direction {313} is about 4%; and the proportion of the silicon grain in the crystal direction {315} is about 17%.

The proportion of the silicon grain area in the total crystal direction in a section occupied by the sum of the area percentage of the silicon grain having the crystal directions {112}, {111} and {115} in any section of the embodiment of polycrystalline silicon brick is more than 50%, and the three crystal directions form the dominant crystal direction group. In an embodiment, any section having three crystal directions {112}, {315} and {115} of the embodiment of polycrystalline silicon brick form the dominant crystal direction group, and the sum of the area percentage of the three crystal directions is more than 50%. In an embodiment, the silicon grains in any section having three crystal directions {112}, {315} and {111} of the embodiment of polycrystalline silicon brick form the dominant crystal direction group, and the sum of the area percentage of the three crystal directions is more than 50%. In an embodiment, the silicon grain in any section having three crystal directions {111}, {115} and {315} of the embodiment of polycrystalline silicon brick form the dominant crystal direction group, and the sum of the area percentage of the three crystal directions is more than 50%. Thus, in any section of the embodiment of polycrystalline silicon brick, any three of the crystal directions {111}, {112}, {115} and {315} form the dominant crystal direction group, and the proportion of the silicon grain area in the total crystal direction in a section occupied by the sum of the area percentage in the three crystal directions is more than 50%.

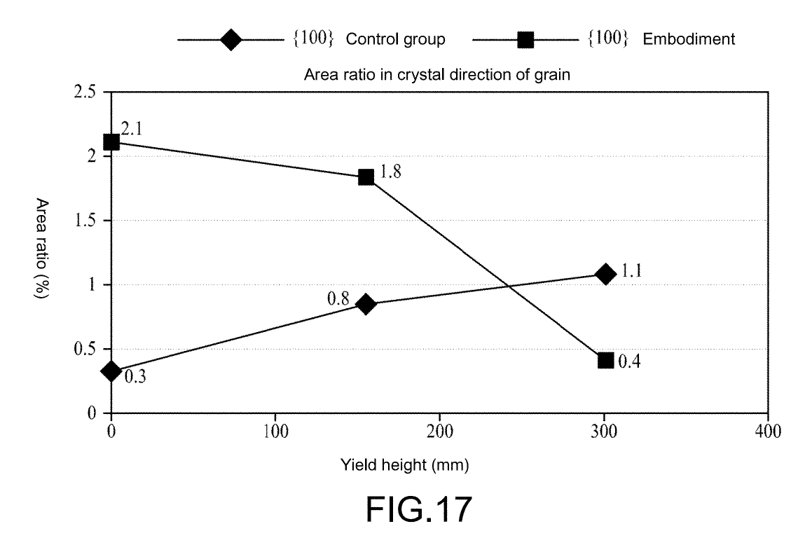

FIG. 17 shows a line graph of a relationship between the yield height and the area ratio in the crystal direction {100} of the embodiment and the control group of polycrystalline silicon brick. The horizontal axis indicates the yield height (unit:mm), and the vertical axis indicates the area ratio in the crystal direction {100}. It can be learned from FIG. 17 that, the area ratio in the crystal direction {100} at the yield height equal to or lower than 200 mm of the embodiment of polycrystalline silicon brick is about 1.4% to 2.1%, which is higher than the area ratio in the crystal direction {100} at the yield height of 200 mm of the control group of polycrystalline silicon brick (less than 1%).

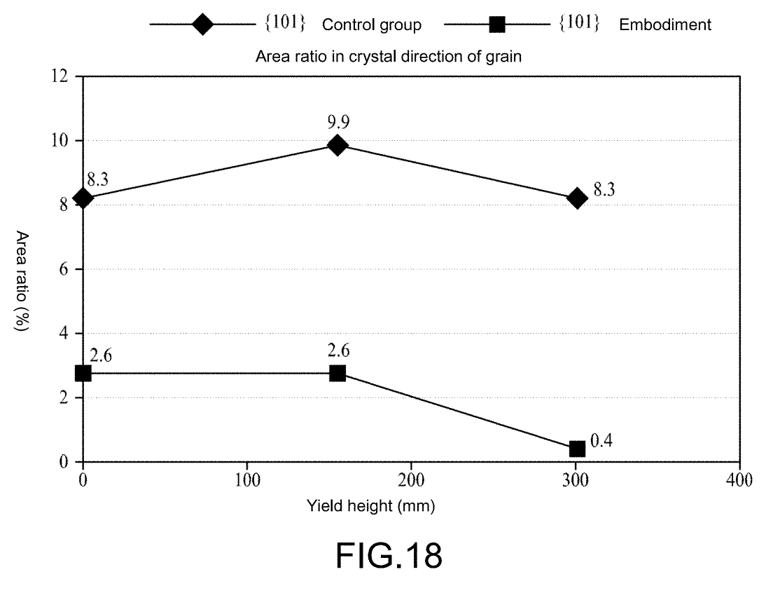

FIG. 18 shows a line graph of a relationship between the yield height and the area ratio in the crystal direction {101} of the embodiment and the control group of polycrystalline silicon brick. The horizontal axis indicates the yield height (unit:mm), and the vertical axis indicates the area ratio in the crystal direction {101}. It can be learned from FIG. 18 that, the area ratio in the crystal direction {101} of the overall embodiment of polycrystalline silicon brick is about 0.4% to 2.6% (less than 3%), which is lower than the area ratio in the crystal direction {101} of the overall control group of polycrystalline silicon brick (about 8.3% to 9.9%).

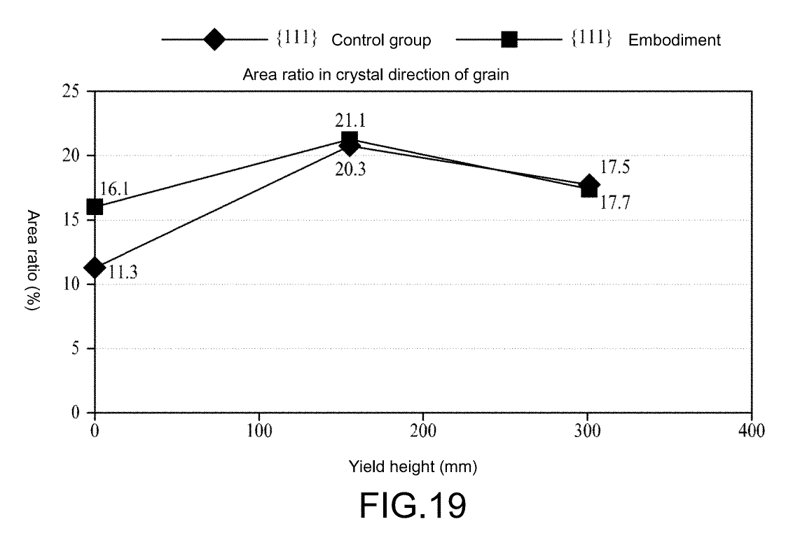

FIG. 19 shows a line graph of a relationship between the yield height and the area ratio in the crystal direction {111} of the embodiment and the control group of polycrystalline silicon brick. The horizontal axis indicates the yield height (unit:mm), and the vertical axis indicates the area ratio in the crystal direction {111}. It can be learned from FIG. 19 that, the area ratio in the crystal direction {111} in each section at the yield height equal to or lower than 100 mm of the embodiment of polycrystalline silicon brick is higher than the area ratio in the crystal direction {111} in each corresponding section at the yield height equal to or lower than 100 mm of the control group of polycrystalline silicon brick.

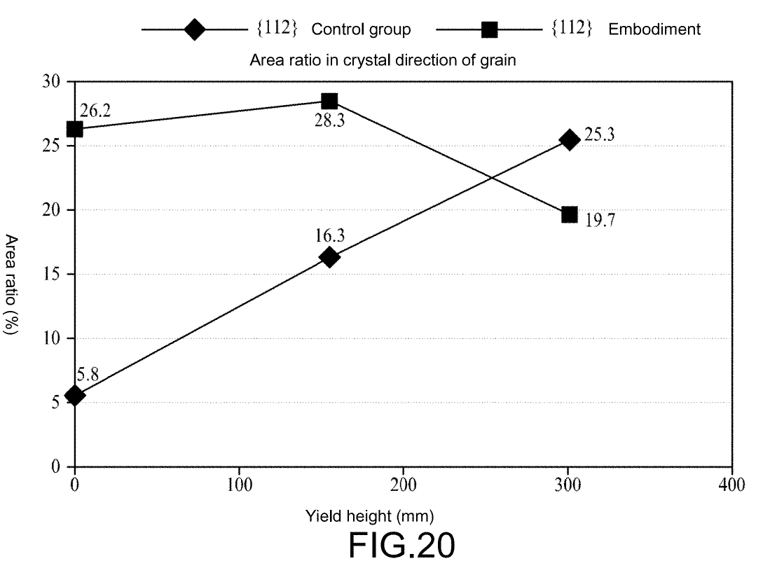

FIG. 20 shows a line graph of a relationship between the yield height and the area ratio in the crystal direction {112} of the embodiment and the control group of polycrystalline silicon brick. The horizontal axis indicates the yield height (unit:mm), and the vertical axis indicates the area ratio in the crystal direction {112}. It can be learned from FIG. 20 that, the area ratio in the crystal direction {112} in each section at the yield height within 200 mm of the embodiment of polycrystalline silicon brick is more than 25%, which is higher than the area ratio in the crystal direction {112} in each section at the yield height within 200 mm of the control group of polycrystalline silicon brick (less than 20%).

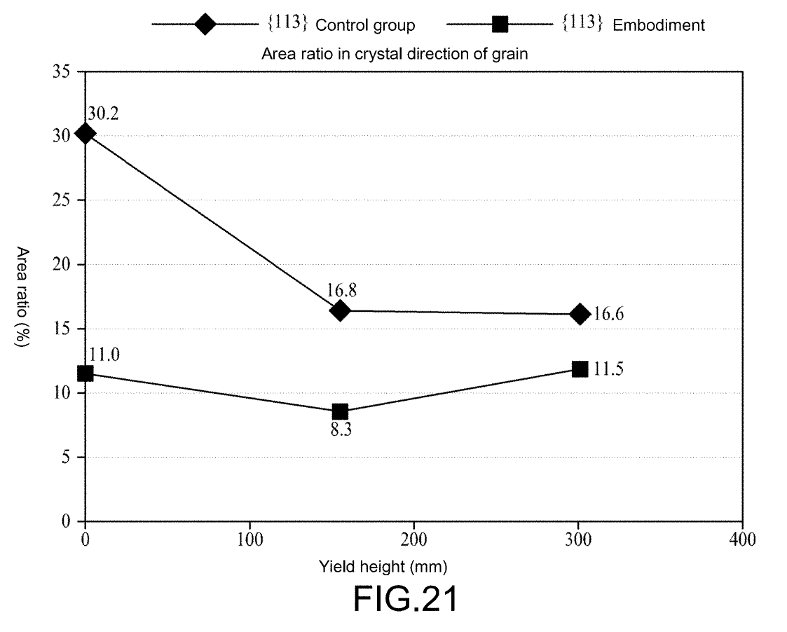

FIG. 21 shows a line graph of a relationship between the yield height and the area ratio in the crystal direction {113} of the embodiment and the control group of polycrystalline silicon brick. The horizontal axis indicates the yield height (unit:mm), and the vertical axis indicates the area ratio in the crystal direction {113}. It can be learned from FIG. 21 that, the area ratio in the crystal direction {113} in each section of the overall embodiment of polycrystalline silicon brick is less than 12%, which is lower than the area ratio in the crystal direction {113} in each section of the overall control group of polycrystalline silicon brick (more than 16%).

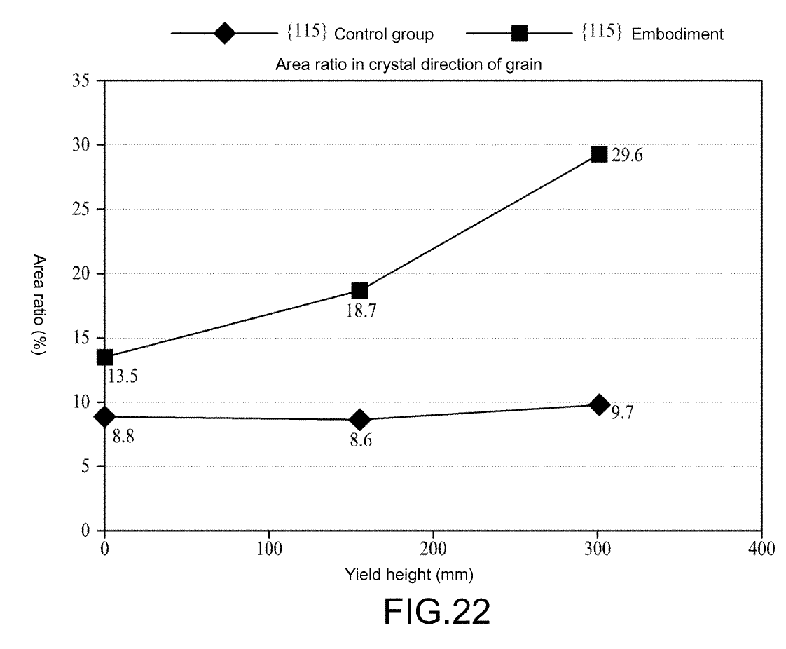

FIG. 22 shows a line graph of a relationship between the yield height and the area ratio in the crystal direction {115} of the embodiment and the control group of polycrystalline silicon brick. The horizontal axis indicates the yield height (unit:mm), and the vertical axis indicates the area ratio in the crystal direction {115}. It can be learned from FIG. 22 that, the area ratio in the crystal direction {115} in each section of the overall embodiment of polycrystalline silicon brick is more than 10%, which is higher than the area ratio in the crystal direction {115} in each section of the overall control group of polycrystalline silicon brick (less than 10%).

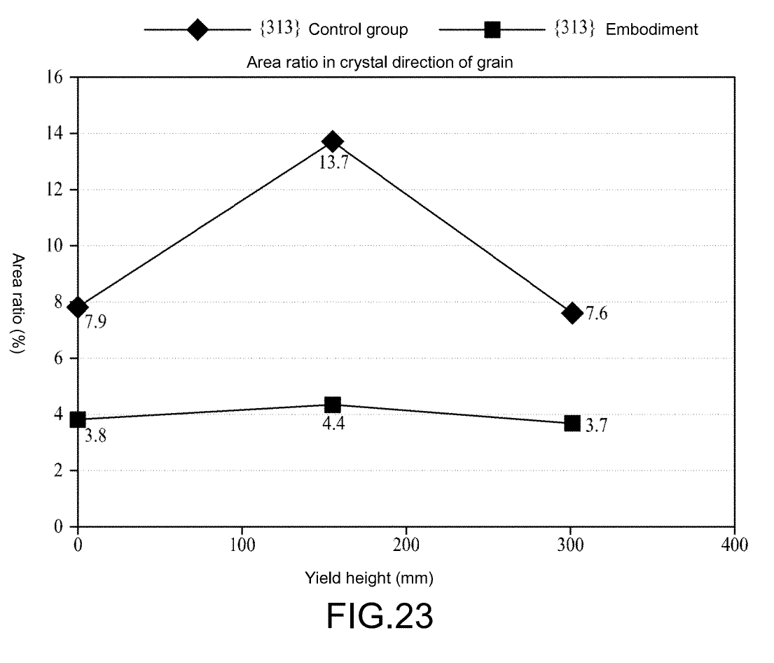

FIG. 23 shows a line graph of a relationship between the yield height and the area ratio in the crystal direction {313} of the embodiment and the control group of polycrystalline silicon brick. The horizontal axis indicates the yield height (unit:mm), and the vertical axis indicates the area ratio in the crystal direction {313}. It can be learned from FIG. 23 that, the area ratio in the crystal direction {313} in each section of the overall embodiment of polycrystalline silicon brick is less than 5%, which is lower than the area ratio in the crystal direction {313} in each section of the overall control group of polycrystalline silicon brick (more than 7%).

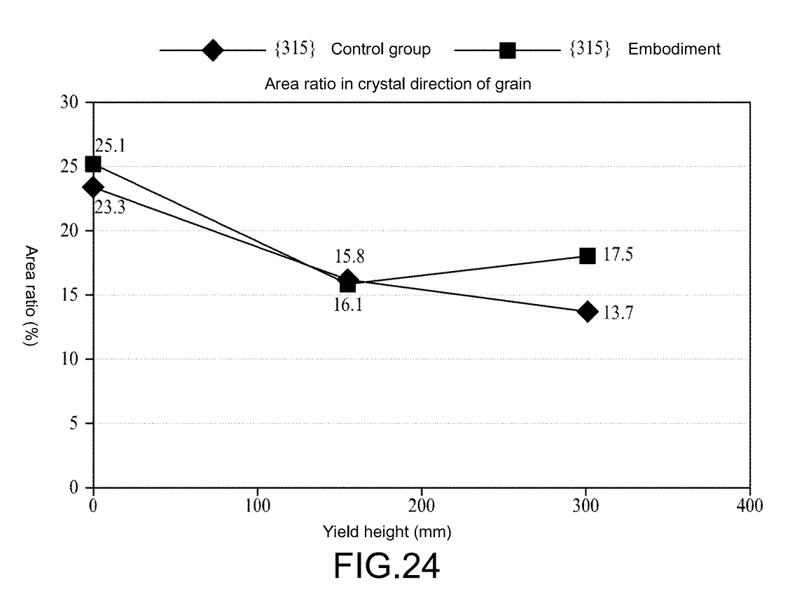

FIG. 24 shows a line graph of a relationship between the yield height and the area ratio in the crystal direction {315} of the embodiment and the control group of polycrystalline silicon brick. The horizontal axis indicates the yield height (unit:mm), and the vertical axis indicates the area ratio in the crystal direction {315}. It can be learned from FIG. 24 that, the area ratio in the crystal direction {315} in each section at the yield height equal to or lower than 100 mm of the embodiment of polycrystalline silicon brick is higher than the area ratio in the crystal direction {315} in each corresponding section at the yield height equal to or lower than 100 mm of the control group of polycrystalline silicon brick.

In summary, in an embodiment, the coefficient of variation of grain area in a section of the embodiment of polycrystalline silicon brick is between about 150% and 400%, and the overall embodiment of polycrystalline silicon brick has better photoelectric conversion efficiency (the average photoelectric conversion efficiency of the embodiment of polycrystalline silicon brick (17.67%) is more than that of the control group of polycrystalline silicon brick (17.20%)), and the minimum value (17.57%) of the photoelectric conversion efficiency of the embodiment of polycrystalline silicon brick is still more than the maximum value (17.40%) of the photoelectric conversion efficiency of the control group of polycrystalline silicon brick. Therefore, the overall embodiment of polycrystalline silicon brick has better photoelectric conversion efficiency. In an embodiment, when the average grain aspect ratio is between 3.80 and 4.25, the photoelectric conversion efficiency is more than 17.60%. Thus, the polycrystalline silicon brick has the best photoelectric conversion efficiency when the average grain aspect ratio thereof is between 3.80 and 4.25. That is, the efficiency of conversion of light energy into electric energy is highest. In an embodiment, the proportion of the random grain boundary length in any section of the embodiment of polycrystalline silicon brick is between about 45% and 70%. The proportion of the random grain boundary is increased to another degree compared to the normal process, so that most of the metal impurities are attracted and accumulated in the grain boundary. Thus, in the growth process of the polycrystalline silicon ingot, the metal impurities which are segregated in the grains can be reduced, thereby enhancing the photoelectric conversion efficiency of the embodiment of polycrystalline silicon brick.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A polycrystalline silicon ingot having a vertical direction, comprising:
a nucleation promotion layer located at a bottom of the polycrystalline silicon ingot; and
a plurality of silicon grains grown along the vertical direction, wherein the plurality of silicon grains comprises at least three crystal directions,
wherein a coefficient of variation of grain area in a section above the nucleation promotion layer of the polycrystalline silicon ingot increases along the vertical direction.

2. The polycrystalline silicon ingot of claim 1, wherein a standard deviation of grain area in the section of the polycrystalline silicon ingot increases along the vertical direction.

3. The polycrystalline silicon ingot of claim 1, wherein the coefficient of variation of grain area in a section above the nucleation promotion layer of the polycrystalline silicon ingot is less than 400%.

4. The polycrystalline silicon ingot of claim 1, wherein the coefficient of variation of grain area in a section above the nucleation promotion layer of the polycrystalline silicon ingot is between 150% and 400%.

5. The polycrystalline silicon ingot of claim 1, wherein an average grain area in a section above the nucleation promotion layer of the polycrystalline silicon ingot is between 4 mm² and 11 mm².

6. The polycrystalline silicon ingot of claim 1, wherein an average grain area in a section above the nucleation promotion layer of the polycrystalline silicon ingot is less than 8 mm².

7. The polycrystalline silicon ingot of claim 1, wherein an average grain aspect ratio in a section above the nucleation promotion layer of the polycrystalline silicon ingot is between 3.0 and 4.5.

8. The polycrystalline silicon ingot of claim 1, wherein an average grain aspect ratio in a section above the nucleation promotion layer of the polycrystalline silicon ingot is between 3.80 and 4.25.
